(19) United States
(12) Patent Application Publication
(10) Pub. No.: US 2025/0142712 A1
(43) Pub. Date: May 1, 2025

(54) DISPLAY APPARATUS AND METHOD FOR MANUFACTURING DISPLAY APPARATUS

(71) Applicant: Samsung Display Co., LTD., Yongin-si (KR)

(72) Inventor: Kyobum KUM, Yongin-si (KR)

(21) Appl. No.: 18/795,417

(22) Filed: Aug. 6, 2024

(30) Foreign Application Priority Data
Oct. 30, 2023 (KR) 10-2023-0146996

(51) Int. Cl. H05K 1/02; H01L 25/16; H10K 59/12; H10K 59/90

(52) U.S. Cl. CPC H05K 1/0213; H01L 25/167; H10K 59/1201; H10K 59/90

(57) ABSTRACT

A display apparatus includes a display panel including a plurality of pixels and a display circuit board which transmits a signal to the display panel and including a first group layer and a second group layer which are sequentially stacked in a thickness direction. The display circuit board includes a body portion including the first group layer and the second group layer, a connecting portion extending from a side of the body portion and including a layer having a same structure as a structure of the first group layer, a connector disposed on an upper portion of the connecting portion, and a reinforcing portion disposed on a lower portion of the connecting portion to overlap the connector in a plan view and including a layer having a same structure as a structure of the second group layer.

This application claims priority to Korean Patent Application No. 10-2023-0146996, filed on Oct. 30, 2023, and all the benefits accruing therefrom under 35 U.S.C. § 119, the content of which in its entirety is herein incorporated by reference.

### BACKGROUND

### 1. Field

Embodiments relate to a display apparatus and a method of manufacturing the same, and more particularly, to a display apparatus including a display circuit board with improved quality and simplified manufacturing processes, and a method of manufacturing the display apparatus.

### 2. Description of the Related Art

Recently, electronic devices are being widely used. Electronic devices are widely used in various forms, such as portable and fixed configurations. Such electronic devices include display apparatuses which provide users with visual information, such as still images or moving images, and supporting various functions.

With the recent advancements in the miniaturization of components for driving display apparatuses, the display apparatuses tend to become increasingly important in electronic devices, and structures that may be bent from a flat state to a specific angle are developed.

In general, a display apparatus includes a display layer disposed over a substrate. In such a display apparatus, at least a portion thereof is bent such that visibility from different angles may be improved or an area of a non-display area may decrease. Specifically, some components, such as a display circuit board, may be arranged in the bent portion of the display apparatus.

### SUMMARY

A connector may be disposed (e.g., mounted) on a display circuit board. In this case, a circuit board on which a connector may be disposed (e.g., mounted) and which may have relatively great quality and simplified manufacturing processes is desired.

Embodiments include a display apparatus and a method of manufacturing the display apparatus, where the manufacturing processes for a display circuit board are simplified and the display apparatus has excellent quality.

However, this is merely illustrative embodiments, and the scope of the disclosure is not limited thereto.

Additional features will be set forth in part in the description which follows and, in part, will be apparent from the description, or may be learned by practice of the presented embodiments of the disclosure.

In an embodiment of the disclosure, a display apparatus includes a display panel including a plurality of pixels, and a display circuit board which transmits a signal to the display panel and including a first group layer and a second group layer which are sequentially stacked in a thickness direction of the display circuit board, where the display circuit board includes a body portion including the first group layer and the second group layer, a connecting portion extending from a side of the body portion and including a layer having a same structure as a structure of the first group layer, a connector disposed on an upper portion of the connecting portion, and a reinforcing portion disposed on a lower portion of the connecting portion to overlap the connector in a plan view and including a layer having a same structure as a structure of the second group layer.

The first group layer of the body portion may be connected to the connecting portion, and the second group layer of the body portion may be discontinued from the connecting portion and the reinforcing portion.

The reinforcing portion may be discontinued from the second group layer of the body portion and disposed in an island shape.

In an embodiment, the reinforcing portion may include at least one conductive layer, and the at least one conductive layer may be exposed and connected to ground.

In an embodiment, the reinforcing portion may include a first conductive layer disposed on a lower portion of the connecting portion, a second conductive layer disposed on a lower portion of the first conductive layer, and an insulating film layer disposed between the first conductive layer and the second conductive layer.

In an embodiment, the reinforcing portion may further include a prepreg layer disposed on the first conductive layer.

In an embodiment, the display circuit board may further include a dam portion disposed under the reinforcing portion and defining an opening exposing at least a portion of the reinforcing portion.

In an embodiment, the body portion may further include a coverlay layer disposed on a lower portion of the second group layer, and the dam portion may include a same material as a material of the coverlay layer.

In an embodiment, the dam portion may be disposed in a loop shape along the periphery of the reinforcing portion.

In an embodiment, the dam portion may further include a rib disposed to cross the opening.

In an embodiment, the rib may be disposed in a grid pattern.

In an embodiment of the disclosure, a method of manufacturing a display apparatus includes forming a display circuit board and connecting the display circuit board to a display panel, where the forming the display circuit board includes forming a stack structure including a body portion by sequentially stacking a first group layer and a second group layer in a thickness direction of the display circuit board, forming a connecting portion connected to the body portion by removing the second group layer from a side of the body portion, and when the second group layer is removed, forming a reinforcing portion by leaving a portion of the second group layer that overlaps a connector to be disposed (e.g., mounted) on the connecting portion, the second group layer being disposed on a lower portion of the connecting portion.

In an embodiment, the method may further include arranging the connector on an upper portion of the connecting portion.

In an embodiment, the second group layer may be discontinued between the body portion and the reinforcing portion.

In an embodiment, the reinforcing portion may be discontinued from the second group layer of the body portion and disposed in an island shape.

In an embodiment, the reinforcing portion may include at least one conductive layer, and the at least one conductive layer may be exposed and connected to ground.

In an embodiment, the reinforcing portion may include a first conductive layer disposed on the lower portion of the connecting portion, a second conductive layer disposed on a lower portion of the first conductive layer, and an insulating film layer disposed between the first conductive layer and the second conductive layer.

In an embodiment, the method may further include forming a dam portion defining an opening defined in a lower portion of the reinforcing portion and exposing at least a portion of the reinforcing portion.

In an embodiment, the dam portion and a coverlay layer may be formed through the same process, the coverlay layer being disposed on a lower portion of the body portion.

In an embodiment, the dam portion may be disposed in a loop shape along the periphery of the reinforcing portion.

Other features and advantages other than those described above will become apparent from the following detailed description, claims and drawings for carrying out the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic plan view of an embodiment of a portion of a display apparatus, showing for convenience of explanation of a state in which a connection circuit board is not bent;

FIG. 2 is a schematic rear view of an embodiment of a portion of a display apparatus, showing a state in which a connection circuit board is bent;

FIG. 3 is a schematic cross-sectional view of a portion of a display apparatus, taken along line III-III′ of FIG. 1;

FIG. 4 is a schematic side view of an embodiment of a display apparatus;

FIG. 5 is a schematic cross-sectional view of an embodiment of a display apparatus, taken along line V-V′ of FIG. 2;

FIG. 6 is a schematic cross-sectional view of an embodiment of a display apparatus similar to that of FIG. 5;

FIG. 7 is a schematic bottom view showing an embodiment of a lower portion of a reinforcing portion and showing the display apparatus of FIG. 6 in a VII direction;

FIG. 8 is a schematic bottom view showing an embodiment of a lower portion of a reinforcing portion, which is similar to FIG. 7; and

FIGS. 9 to 12 are schematic diagrams of an embodiment of a method of manufacturing a display apparatus.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Hereinafter, embodiments of the disclosure will be described in detail with reference to the accompanying drawings. Like elements in the drawings denote like elements, and repeated descriptions thereof are omitted.

It will be understood that although the terms “first,” “second,” etc. may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, it may be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

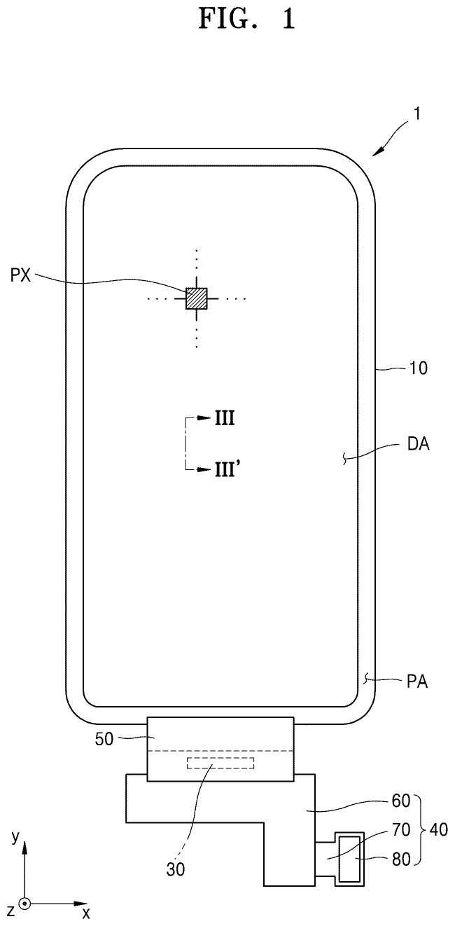

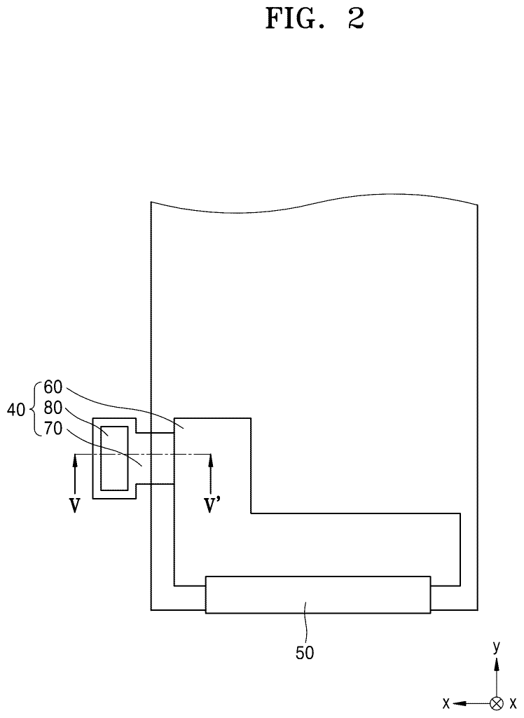

FIG. 1 is a schematic plan view of an embodiment of a portion of a display apparatus. FIG. 1 shows a state in which a connection circuit board is not bent, for convenience of explanation. FIG. 2 is a schematic rear view of an embodiment of a portion of a display apparatus. FIG. 2 shows a state in which the connection circuit board is bent.

Referring to FIGS. 1 and 2, a display apparatus 1 may display a moving image or a still image and may be used as a display screen of various products, e.g., a portable electronic device, such as a mobile phone, a smartphone, a tablet personal computer (“PC”), a mobile communication terminal, a personal digital assistant, an e-book terminal, a portable multimedia player (“PMP”), a navigation device, or an ultra-mobile PC (“UMPC”), a television (“TV”), a laptop, a monitor, a billboard, an Internet of Things (“IoT”) device, or the like. Also, in an embodiment, the display apparatus 1 may be used in a wearable device, such as a smartwatch, a watch phone, an eyewear display, or a head-mounted display (“HMD”). Also, in an embodiment, the display apparatus 1 may be used as a display screen in an instrument cluster of a vehicle, a center information display (“CID”) disposed (e.g., mounted) on a center fascia or a dashboard of a vehicle, a room mirror display replacing a side-view mirror of a vehicle, or a car headrest monitor provided for rear-seat entertainment.

As shown in FIG. 1, the shape of the display apparatus 1 may be substantially a rectangle. As shown in FIG. 1, e.g., the display apparatus 1 may have a quadrangular planar shape, e.g., rectangular planar shape having short sides extending in a first direction (e.g., an x direction or a −x direction) and long sides extending in a second direction (e.g., a y direction or a −y direction). In an embodiment, a portion, in which the short side extending in the first direction (e.g., the x direction or the −x direction) meets the long side extending in the second direction (e.g., the y direction or the −y direction), may have a right-angled shape or a round shape with certain curvature. The planar shape of the display apparatus 1 is not limited to the rectangle and may be a polygon, a circle, or an oval.

The display apparatus 1 may include a display area DA and a peripheral area PA. In the display area DA, images may be displayed. In the display area DA, a plurality of pixels PX may be arranged. The display apparatus 1 may provide images by light emitted from the plurality of pixels PX. Each of the plurality of pixels PX may emit light by a display element. In an embodiment, each of the plurality of pixels PX may emit red light, green light, or blue light. In an embodiment, each of the plurality of pixels PX may emit red light, green light, blue light, or white light.

The peripheral area PA is an area where no images are displayed and may be a non-display area. The peripheral area PA may at least partially surround the display area DA. In an embodiment, the peripheral area PA may surround an entirety of the display area DA, for example. In the peripheral area PA, drivers which provide electrical signals to the plurality of pixels PX, power lines which supply power to the plurality of pixels PX, or the like may be arranged. In an embodiment, a scan driver which applies scan signals to the plurality of pixels PX may be arranged in the peripheral area PA, for example. Also, a data driver which applies data signals to the plurality of pixels PX may be arranged in the peripheral area PA.

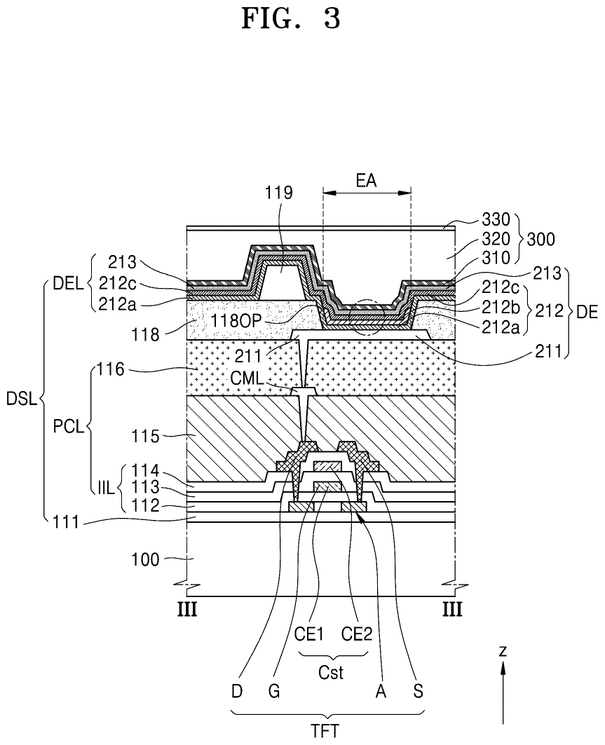

FIG. 3 is a schematic cross-sectional view of a portion of a display apparatus, taken along line III-III′ of FIG. 1.

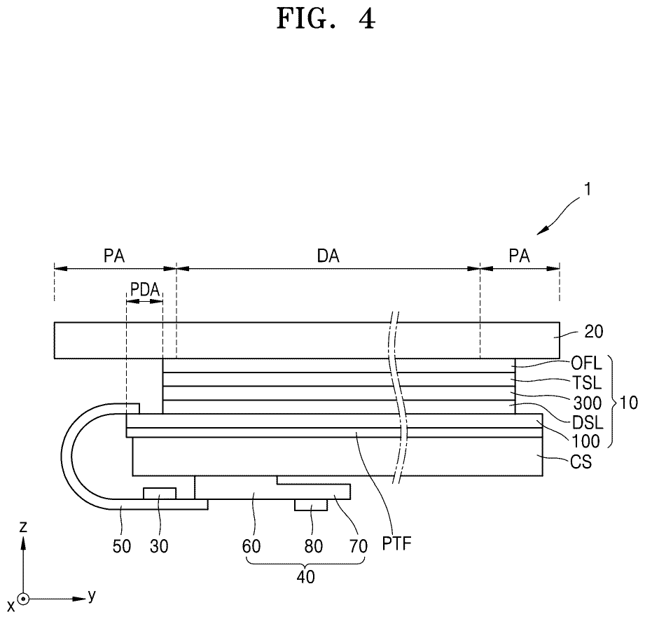

Referring to FIG. 3 along with FIG. 1, the display apparatus 1 may include a display panel 10. The display panel 10 may include a substrate 100, a display layer DSL, an encapsulation layer 300, a touch sensor layer TSL, and an optical functional layer OFL. For convenience of explanation, the touch sensor layer TSL and the optical functional layer OFL are omitted in FIG. 3, which is described below in detail with reference to FIG. 4.

The display layer DSL may be disposed over the substrate 100. The display layer DSL may include a buffer layer 111, a pixel circuit layer PCL, and a display element layer DEL.

The substrate 100 may include glass or polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. The substrate 100 including polymer resin may be flexible, rollable, or bendable. The substrate 100 may have a multilayered structure that includes a base layer including the above polymer resin and a barrier layer (not shown).

The buffer layer 111 may include inorganic insulating materials, such as silicon nitride (SiNₓ), silicon oxynitride (SiON), or silicon oxide (SiO₂), and may be a layer or layers including the inorganic insulating materials.

The pixel circuit layer PCL may be disposed over the buffer layer 111. The pixel circuit layer PCL may include a transistor TFT included in a pixel circuit, and an inorganic insulating layer IIL, a first planarization layer 115, and a second planarization layer 116 which are disposed under and/or above components of the transistor TFT. The inorganic insulating layer IIL may include a first gate insulating layer 112, a second gate insulating layer 113, and an inter-insulating layer 114.

The transistor TFT may include a semiconductor layer A, and the semiconductor layer A may include polysilicon. In an alternative embodiment, the semiconductor layer A may include amorphous silicon, an oxide semiconductor, an organic semiconductor, or the like. The semiconductor layer A may include a channel area and a source area and a drain area located on opposite sides of the channel area. A gate electrode G may overlap the channel area.

The gate electrode G may include a low-resistive metal material. The gate electrode G may include a conductive material including molybdenum (Mo), aluminum (Al), copper (Cu), or titanium (Ti) and may be a layer or layers including the above material.

The first gate insulating layer 112 between the semiconductor layer A and the gate electrode G may include an inorganic insulating material, such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnOₓ). ZnOₓ may be ZnO and/or ZnO₂.

The second gate insulating layer 113 may cover the gate electrode G. Similarly to the first gate insulating layer 112, the second gate insulating layer 113 may include an inorganic insulating material, such as SiO₂, SiNₓ, SiON, Al₂O₃, TiO₂, Ta₂O₅, HfO₂, or ZnOₓ. ZnOₓ may be ZnO and/or ZnO₂.

An upper electrode CE2 of a storage capacitor Cst may be disposed over the second gate insulating layer 113. The upper electrode CE2 may overlap the gate electrode G disposed thereunder. In this case, the gate electrode G and the upper electrode CE2, which overlap each other with the second gate insulating layer 113 therebetween, may form the storage capacitor Cst of the pixel circuit. That is, the gate electrode G may function as a lower electrode CE1 of the storage capacitor Cst. As described, the storage capacitor Cst may overlap the transistor TFT. In some embodiments, the storage capacitor Cst may not overlap the transistor TFT.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu and may be a layer or layers including the above material.

The inter-insulating layer 114 may cover the upper electrode CE2. The inter-insulating layer 114 may include SiO₂, SiN_{X}, SiON, Al₂O₃, TiO₂, Ta₂O₅, HfO₂, ZnOₓ, or the like. ZnOₓ may be ZnO and/or ZnO₂. The inter-insulating layer 114 may be a layer or layers including the above inorganic insulating material.

A drain electrode D and a source electrode S may each be disposed over the inter-insulating layer 114. The drain electrode D and the source electrode S may each include a material with good conductivity. The drain electrode D and the source electrode S may each include a conductive material including Mo, Al, Cu, or Ti and may be a layer or layers including the above material. In an embodiment, the drain electrode D and the source electrode S may have a multilayered structure of Ti/Al/Ti.

The first planarization layer 115 may cover the drain electrode D and the source electrode S. The first planarization layer 115 may include an organic insulating layer. The first planarization layer 115 may include organic insulating materials, such as a general-purpose polymer such as polymethylmethacrylate (“PMMA”) or polystyrene (“PS”), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any combinations thereof.

A connection electrode CML may be disposed over the first planarization layer 115. In this case, the connection electrode CML may be connected to the drain electrode D or the source electrode S through a contact hole in the first planarization layer 115. The connection electrode CML may include a material with good conductivity. The connection electrode CML may include a conductive material including Mo, Al, Cu, or Ti and may be a layer or layers including the above material. In an embodiment, the connection electrode CML may have a multilayered structure of Ti/Al/Ti.

The second planarization layer 116 may cover the connection electrode CML. The second planarization layer 116 may include an organic insulating layer. The second planarization layer 116 may include organic insulating materials, such as a general-purpose polymer such as PMMA or PS, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and any combinations thereof.

The display element layer DEL may be disposed over the pixel circuit layer PCL. The display element layer DEL may include a display element DE. The display element DE may be an organic light-emitting diode (“OLED”). A pixel electrode 211 of the display element DE may be electrically connected to the connection electrode CML through a contact hole in the second planarization layer 116.

The pixel electrode 211 may include conductive oxide, such as indium tin oxide (“ITO”), indium zinc oxide (“IZO”), ZnO, indium oxide (In₂O₃), indium gallium oxide (“IGO”), or aluminum zinc oxide (“AZO”). In an embodiment, the pixel electrode 211 may include a reflection film including Ag, Mg, Al, Pt, Pd, Au, Ni, Nd, Ir, Cr, or any combinations thereof. In another embodiment, the pixel electrode 211 may further include a film including ITO, IZO, ZnO, or In₂O₃ on/under the above reflection film.

A pixel-defining layer 118 defining an opening 118OP may be disposed over the pixel electrode 211, the opening 118OP exposing a central portion of the pixel electrode 211. The pixel-defining layer 118 may include an organic insulating material and/or an inorganic insulating material. The opening 118OP may define an emission area EA of light emitted from the display element DE (hereinafter, also referred to as an emission area). In an embodiment, the width of the opening 118OP may correspond to that of the emission area EA of the display element DE, for example.

A spacer 119 may be disposed over the pixel-defining layer 118. The spacer 119 may prevent damage to the substrate 100 in the method of manufacturing a display apparatus. A mask sheet may be used during the manufacturing of the display panel, and in this case, defects, such as damage to a portion of the substrate 100 or breakage of the substrate 100 by the mask sheet when a deposition material is deposited on the substrate 100, may be prevented, where such defects are caused when the mask sheet enters the opening 118OP of the pixel-defining layer 118 or adheres to the pixel-defining layer 118.

The spacer 119 may include an organic insulating material, such as polyimide. In an alternative embodiment, the spacer 119 may include an inorganic insulating material, such as SiNₓ or SiO₂, or both an organic insulating material and an inorganic insulating material.

In an embodiment, the spacer 119 may include a different material from that of the pixel-defining layer 118. In an alternative embodiment, in another embodiment, the spacer 119 may include the same material as that of the pixel-defining layer 118, and in this case, the pixel-defining layer 118 and the spacer 119 may be formed together through a mask process using a halftone mask, etc.

An intermediate layer 212 may be disposed over the pixel-defining layer 118. The intermediate layer 212 may include an emission layer 212b disposed in the opening 118OP of the pixel-defining layer 118. The emission layer 212 may include a high-molecular-weight or low-molecular-weight organic material emitting a predetermined color of light.

A first functional layer 212a and a second functional layer 212c may be disposed under and above the emission layer 212b. The first functional layer 212a may include, e.g., a hole transport layer (“HTL”) or both an HTL and a hole injection layer (“HIL”). The second functional layer 212c may be disposed over the emission layer 212b and optional. The second functional layer 212c may include an electron transport layer (“ETL”) and/or an electron injection layer (“EIL”). The first functional layer 212a and/or the second functional layer 212c may each be a common layer formed to cover an entirety of the substrate 100 like an opposite electrode 213 described below.

The opposite electrode 213 may include a conductive material having a relatively low work function. In an embodiment, the opposite electrode 213 may include a transparent (or translucent) layer including Ag, Mg, Al, Pt, Pd, Au, Ni, Nd, Ir, Cr, lithium (Li), calcium (Ca), or any alloys thereof, for example. In an alternative embodiment, the opposite electrode 213 may further include a layer including ITO, IZO, ZnO, or In₂O₃ on the transparent (or translucent) layer including the above material.

In some embodiments, a capping layer (not shown) may be further disposed over the opposite electrode 213. The capping layer may include LiF, an inorganic material, and/or an organic material.

The encapsulation layer 300 may be disposed over the opposite electrode 213. The encapsulation layer 300 may be disposed over the display element layer DEL and cover the same. The encapsulation layer 300 may include at least one inorganic encapsulation layer and at least one organic encapsulation layer, and in an embodiment, FIG. 3 shows that the encapsulation layer 300 includes a first inorganic encapsulation layer 310, an organic encapsulation layer 320, and a second inorganic encapsulation layer 330 which are sequentially stacked.

The first inorganic encapsulation layer 310 and the second inorganic encapsulation layer 330 may each include one or more inorganic materials selected from among Al₂O₃, TiO₂, Ta₂O₅, HfO₂, ZnOₓ, SiO₂, SiNₓ, and SiON. The organic encapsulation layer 320 may include a polymer-based material. The polymer-based material may include acrylic resin, epoxy-based resin, polyimide, polyethylene, or the like. In an embodiment, the organic encapsulation layer 320 may include acrylate. The organic encapsulation layer 320 may be formed by curing a monomer or applying a polymer. The organic encapsulation layer 320 may be transparent.

Although not shown on the encapsulation layer 300, the touch sensor layer described above may be disposed, and an optical functional layer may be disposed over the touch sensor layer.

FIG. 4 is a schematic side view of an embodiment of a display apparatus.

Referring to FIG. 4, the display apparatus 1 may include a display panel 10, a cover window 20, a display driver 30, a display circuit board 40, a connection circuit board 50, a cushion layer CS, and a protective film PTF.

The display panel 10 may display information processed in the display apparatus 1. In an embodiment, the display panel 10 may display information regarding an execution screen of an application executed on the display apparatus 1, or user interface (“UI”) information or graphics user interface (“GUI”) information according to the information regarding the execution screen, for example.

The display panel 10 may include a display element. In an embodiment, the display panel 10 may be an organic light-emitting display panel using organic light-emitting diodes, a micro light-emitting diode (“LED”) display panel using micro-LEDs, a quantum dot light-emitting display panel using quantum dot LEDs including quantum dot emission layers, or an inorganic light-emitting display panel using inorganic LEDs including inorganic semiconductors, for example. Hereinafter, a case where the display panel 10 is an organic light-emitting display panel using organic light-emitting diodes as display elements is described in detail.

The display panel 10 may include the substrate 100 and a multilayered film disposed over the substrate 100. In an embodiment, the display panel 10 may include the substrate 100, the display layer DSL, the encapsulation layer 300, the touch sensor layer TSL, and the optical functional layer OFL. In this case, the display area DA and the peripheral area PA may be defined in the substrate 100 and/or the multilayered film. In an embodiment, it may be described that the substrate 100 includes the display area DA and the peripheral area PA, for example. Also, the peripheral area PA may include a pad area PDA projected from a side of the peripheral area PA.

The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multilayered structure that includes a base layer including the above polymer resin and a barrier layer (not shown). The substrate 100 including polymer resin may be flexible, rollable, or bendable.

The display layer DSL may be disposed over the substrate 100. The display layer DSL may include pixel circuits and display elements. In this case, each pixel circuit may be connected to each display element. The pixel circuit may include a thin-film transistor and a storage capacitor. Therefore, the display layer DSL may include a plurality of display elements, a plurality of thin-film transistors, and a plurality of storage capacitors. Also, the display layer DSL may further include a plurality of insulating layers interposed therebetween.

The encapsulation layer 300 may be disposed over the display layer DSL. The encapsulation layer 300 may be disposed over the display element and cover the same. In an embodiment, the encapsulation layer 300 may include at least one inorganic encapsulation layer and at least one organic encapsulation layer. At least one inorganic encapsulation layer may include one or more inorganic materials selected from among Al₂O₃, TiO₂, Ta₂O₅, ZnO, SiO₂, SiNₓ, and SiON. At least one organic encapsulation layer may include a polymer-based material. The polymer-based material may include acrylic resin, epoxy-based resin, polyimide, polyethylene, or the like. In an embodiment, at least one organic encapsulation layer may include acrylate.

The touch sensor layer TSL may be disposed over the encapsulation layer 300. The touch sensor layer TSL may sense coordinate information according to an external input, e.g., a touch event. The touch sensor layer TSL may include a sensor electrode and touch lines connected to the sensor electrode. The touch sensor layer TSL may sense an external input in a self-capacitive manner or a mutual-capacitive manner.

The touch sensor layer TSL may be formed on the encapsulation layer 300. In an alternative embodiment, after the touch sensor layer TSL is separately formed on a touch substrate, the touch sensor layer TSL may be coupled to the encapsulation layer 300 by an adhesive layer, such as an optically clear adhesive (“OCA”). In an embodiment, the touch sensor layer TSL may be formed directly on the encapsulation layer 300, and in this case, no adhesive layer may be interposed between the touch sensor layer TSL and the encapsulation layer 300.

The optical functional layer OFL may be disposed over the touch sensor layer TSL. The optical functional layer OFL may reduce the reflectivity of light (external light) that is incident towards the display apparatus 1 from the outside and/or may improve the color purity of light emitted from the display apparatus 1. In an embodiment, the optical functional layer OFL may include a retarder and a polarizer. The retarder may be of a film type or a liquid crystal coating type and may include a λ/2 retarder and/or a λ/4 retarder. The polarizer may also be of a film type or a liquid crystal coating type. The film type may include a stretched synthetic resin film, and the liquid crystal coating type may include liquid crystals arranged in a predetermined arrangement. The retarder and the polarizer may further include a protective film.

In another embodiment, the optical functional layer OFL may include a black matrix and color filters. The color filters may be arranged considering colors of light respectively emitted from the pixels of the display apparatus 1. Each color filter may include a red, green, or blue pigment or dye. In an alternative embodiment, each color filter may further include quantum dots in addition to the above pigment or dye. In an alternative embodiment, some of the color filters may not include the above pigment or dye and may include scattered particles, such as TiO₂.

In another embodiment, the optical functional layer OFL may include a destructive interference structure. The destructive interference structure may include a first reflection layer and a second reflection layer arranged in different layers. First reflection light and second reflection light, which are respectively reflected from the first reflection layer and the second reflection layer, may destructively interfere with each other, and the reflectivity of external light may decrease accordingly.

The cover window 20 may be disposed over the display panel 10. The cover window 20 may protect the display panel 10. In an embodiment, the cover window 20 may be a flexible window. The cover window 20 may be easily bent by external force without the generation of cracks, etc., thus providing protection for the display panel 10. The cover window 20 may include at least one of glass, sapphire, and plastic. The cover window 20 may be, e.g., ultra-thin glass (“UTG”) or colorless polyimide (“CPI”). In an embodiment, the cover window 20 may have a structure in which a flexible polymer layer is disposed on one surface of a glass substrate, or may only include a polymer layer.

The cover window 20 may be attached to the display panel 10 by an adhesive member. The adhesive member may be a colorless adhesive member, such as an OCA. Besides, the adhesive member may include well-known adhesive materials. Such an adhesive member may be formed on the upper portion of the display panel 10 in various manner; for example, a film-type adhesive member may be attached to the upper portion of the display panel 10, or a material-type adhesive member may be applied to the upper portion of the display panel 10.

The connection circuit board 50 may be connected to the display panel 10. An end portion of the connection circuit board 50 may be connected to the display panel 10, e.g., the pad area PDA of the substrate 100. The pad area PDA of the substrate 100 may extend on one side of the peripheral area PA and include a plurality of pad portions which may be electrically connected to the connection circuit board 50.

In an embodiment, the connection circuit board 50 may be a flexible printed circuit board. In an embodiment, the connection circuit board 50 may be an anisotropic conductive film, for example. The connection circuit board 50 may have an end portion connected to the pad area PDA and be bent in a U shape. Therefore, an area of the peripheral area PA viewed by a user may be reduced.

The display driver 30 may be disposed on the connection circuit board 50. The display driver 30 may receive control signals and power voltages and generate and output signals and voltages for driving the display panel 10. The display driver 30 may include an integrated circuit (“IC”). In an embodiment, the display driver 30 may be disposed on a surface of the connection circuit board 50 that faces the cushion layer CS.

An opposite end portion of the connection circuit board 50 may be connected to the display circuit board 40. In an embodiment, the pad portion of the connection circuit board 50 may contact the pad portion of the display circuit board 40 and thus be electrically connected thereto, for example. Because the connection circuit board 50 is bent in the U shape and extends to the rear surface of the display surface of the display panel 10, the display circuit board 40 may be disposed on the rear surface of the display surface of the display panel 10. In an embodiment, the display circuit board 40 may be attached to the cushion layer CS by an adhesive member.

The display circuit board 40 may be a flexible printed circuit board (“FPCB”) that may be bent, or a rigid printed circuit board (“PCB”) that is rigid and hardly bent. In an alternative embodiment, in some cases, the display circuit board 40 may be a composite PCB including both the rigid PCB and the FPCB, for example.

Although not shown, various drivers may be arranged on the display circuit board 40. In an embodiment, a touch sensor driver may be disposed on the display circuit board 40. The touch sensor driver may include an IC, for example. The touch sensor driver may be electrically connected to sensor electrodes of the touch sensor layer TSL of the display panel 10 through the display circuit board 40.

In addition to this, a power supply may be additionally disposed on the display circuit board 40. The power supply may supply a driving voltage for driving the pixels of the display panel 10 and the display driver 30.

The protective film PTF may be patterned and attached to a lower surface of the substrate 100. That is, the protective film PTF may be disposed between the substrate 100 and the cushion layer CS.

In an embodiment, the cushion layer CS may be disposed under the display panel 10, particularly, the substrate 100. The cushion layer CS may prevent damage to the display panel 10 by absorbing external impact. The cushion layer CS may include polymer resin, such as polyurethane, polycarbonate, polypropylene, or polyethylene or an elastic material, e.g., a sponge that is obtained by foam-molding rubber, urethane-based materials or acryl-based materials

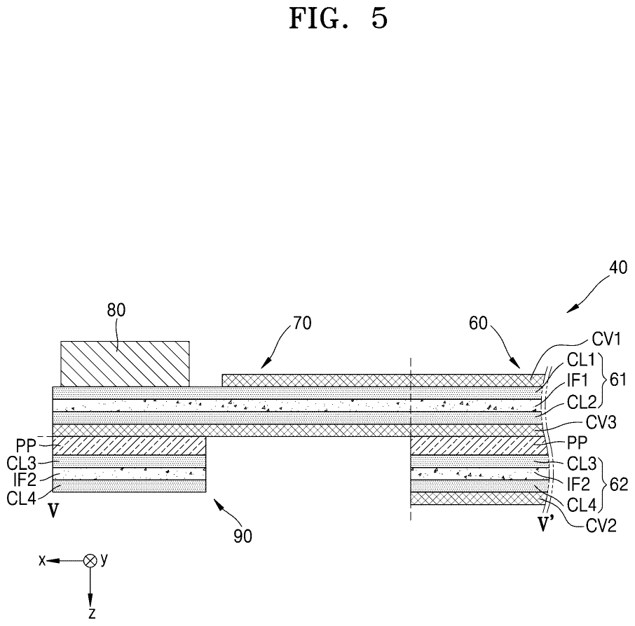

FIG. 5 is a schematic cross-sectional view of an embodiment of a display apparatus, taken along line V-V′ of FIG. 2. For convenience of explanation, the display circuit board 40 is mainly illustrated, and the display panel 10 or the like are omitted.

Referring to FIGS. 2 and 5, the display circuit board 40 may include at least one conductive layer and at least one insulating film layer. In an embodiment, the display circuit board 40 may include a body portion 60, a connecting portion 70, and a reinforcing portion 90.

The body portion 60 may include a first group layer 61 and a second group layer 62. The first group layer 61 and the second group layer 62 may be sequentially stacked in a thickness direction of the display circuit board 40 (e.g., the −z direction of FIG. 5). That is, as shown in FIG. 5, the first group layer 61 may be disposed over the second group layer 62. Each of the first group layer 61 and the second group layer 62 may have a multilayered structure.

The first group layer 61 may include at least one conductive layer and at least one insulating film layer. In an embodiment, the first group layer 61 may include a first insulating film layer IF1, a first conductive layer CL1, and a second conductive layer CL2. The first conductive layer CL1 and the second conductive layer CL2 may be arranged on opposite sides of the first insulating film layer IF1. The first insulating film layer IF1 may maintain the rigidity of the display circuit board 40 and protect a signal from the outside. In addition, the first insulating film layer IF1 may prevent the generation of cracks in the first conductive layer CL1 and the second conductive layer CL2. The first insulating film layer IF1 may include polyimide.

The first conductive layer CL1 may be disposed on a surface, e.g., an upper surface (a surface in the −z direction of FIG. 5), of the first insulating film layer IF1. The second conductive layer CL2 may be disposed on an opposite surface, e.g., a lower surface (a surface in the +z direction of FIG. 5), of the first insulating film layer IF1. The first conductive layer CL1 and the second conductive layer CL2 may include conductive materials. In an embodiment, the first conductive layer CL1 and the second conductive layer CL2 may include Cu, for example.

In an embodiment, the first group layer 61 of the display circuit board 40 may define a through hole (not shown) which electrically connects the first conductive layer CL1 to the second conductive layer CL2. In detail, the through hole may be an opening penetrating the first conductive layer CL1, the second conductive layer CL2, and the first insulating film layer IF1. An inner side surface of the through hole may be covered by a conductor, such as a plating material. Accordingly, the conductor may be electrically connected to the first conductive layer CL1 on one side of the conductor and the second conductive layer CL2 on an opposite side of the conductor, thus connecting signals from the first conductive layer CL1 and the second conductive layer CL2. Also, such a through hole may be provided in the plural.

The second group layer 62 may be disposed under the first group layer 61. That is, the second group layer 62 may be arranged closer to the display panel 10 and/or the cushion layer CS than the first group layer 61 in the thickness direction of the display circuit board 40. The second group layer 62 may include at least one conductive layer and at least one insulating film layer. In an embodiment, the second group layer 62 may include a second insulating film layer IF2, a third conductive layer CL3, and a fourth conductive layer CL4. The third conductive layer CL3 and the fourth conductive layer CL4 may be arranged on both surfaces of the second insulating film layer IF2. The second insulating film layer IF2 may maintain the rigidity of the display circuit board 40 and protect a signal from the outside. In addition, the second insulating film layer IF2 may prevent the generation of cracks in the third conductive layer CL3 and the fourth conductive layer CL4. The second insulating film layer IF2 may include polyimide.

The third conductive layer CL3 may be disposed on a surface, e.g., an upper surface (a surface in the −z direction of FIG. 5), of the second insulating film layer IF2. The fourth conductive layer CL4 may be disposed on an opposite surface, e.g., a lower surface (a surface in the +z direction of FIG. 5), of the second insulating film layer IF2. The third conductive layer CL3 and the fourth conductive layer CL4 may include conductive materials. In an embodiment, the third conductive layer CL3 and the fourth conductive layer CL4 may include Cu, for example.

In an embodiment, the second group layer 62 of the display circuit board 40 may define a through hole (not shown) which electrically connects the third conductive layer CL3 to the fourth conductive layer CL4. In detail, the through hole may be an opening penetrating the third conductive layer CL3, the fourth conductive layer CL4, and the second insulating film layer IF2. An inner side surface of the through hole may be covered by a conductor, such as a plating material. Accordingly, the conductor may be electrically connected to the third conductive layer CL3 on one side of the conductor and the fourth conductive layer CL4 on an opposite side of the conductor, thus connecting signals from the third conductive layer CL3 and the fourth conductive layer CL4. Also, such a through hole may be provided in the plural.

It has been described that the first group layer 61 includes the first insulating film layer IF1, the first conductive layer CL1, and the second conductive layer CL2 and the second group layer 62 includes the second insulating film layer IF2, the third conductive layer CL3, and the fourth conductive layer CL4, but the disclosure is not limited thereto. As described below in detail, the first group layer 61 may refer to a structure layer that is continuously connected to the connecting portion 70 from the body portion 60. The second group layer 62 may be a portion that is not connected to the connecting portion 70 but is discontinuous. That is, the second group layer 62 may refer to a portion of the structure layer that is not included in the connecting portion 70 or is removed from the display circuit board 40. Therefore, the first group layer 61 may include more or fewer layers. In addition, the second group layer 62 may also include more or fewer layers. Hereinafter, for convenience of explanation, the first group layer 61 includes the first insulating film layer IF1, the first conductive layer CL1, and the second conductive layer CL2, and the second group layer 62 includes the second insulating film layer IF2, the third conductive layer CL3, and the fourth conductive layer CL4.

An upper portion of the first group layer 61 (in the −z direction of FIG. 5) and a lower portion of the second group layer 62 (in the +z direction of FIG. 5) may be covered by a coverlay layer. That is, an exposed surface of the conductive layer of each of the first group layer 61 and the second group layer 62 may be covered by the coverlay layer. In an embodiment, the upper portion of the first group layer 61 may be covered by a first coverlay layer CV1. In an embodiment, the first coverlay layer CV1 may be disposed over the first conductive layer CL1, for example. The lower portion of the second group layer 62 may be covered by a second coverlay layer CV2. In an embodiment, the second coverlay layer CV2 may be disposed under the fourth conductive layer CL4. The first coverlay layer CV1 and the second coverlay layer CV2 may protect exposed conductive layers, for example. Also, in an embodiment, a third coverlay layer CV3 may be further disposed between the first group layer 61 and the second group layer 62, but the disclosure is not limited thereto. The third coverlay layer CV3 may be omitted. In an embodiment, the first coverlay layer CV1, the second coverlay layer CV2, and the third coverlay layer CV3 may each include polyimide.

The second group layer 62 may adhere to the first group layer 61 by a prepreg layer PP. In other words, the prepreg layer PP may be between the second group layer 62 and the first group layer 61 to connect the same. Also, when the third coverlay layer CV3 is disposed, the second group layer 62 may adhere to the third coverlay layer CV3 by the prepreg layer PP.

The connecting portion 70 may extend from one side of the body portion 60. As shown in FIGS. 2 and 5, the connecting portion 70 may extend from the body portion 60 and embed the connector 80 therein. In an embodiment, the connecting portion 70 may include a layer having the same structure as that of the first group layer 61 of the body portion 60. In an embodiment, the connecting portion 70 may include the first conductive layer CL1, the first insulating film layer IF1, and the second conductive layer CL2 which are sequentially stacked, for example. Each layer of the connecting portion 70 may be continuously connected to each layer of the first group layer 61. The first conductive layer CL1 and the second conductive layer CL2 of the connecting portion 70 may be respectively covered by the first coverlay layer CV1 and the third coverlay layer CV3 like the first group layer 61.

In this case, the connecting portion 70 may not include layers corresponding to the second group layer 62 of the body portion 60. The connecting portion 70 may be discontinued from the second group layer 62 of the body portion 60. In other words, a layer removed from the connecting portion 70 among the respective layers of the display circuit board 40 may be defined as the second group layer 62.

A portion of the first coverlay layer CV1 on the connecting portion 70 may be removed, and thus, the first conductive layer CL1 may be exposed. The connector 80 may be disposed over the exposed first conductive layer CL1 of the connecting portion 70. The connector 80 may be electrically connected to the connecting portion 70 and the body portion 60 through the first conductive layer CL1. In detail, at least one terminal may be disposed over the exposed first conductive layer CL1 of the connecting portion 70, and the connector 80 may be electrically connected to the first conductive layer CL1 of the connecting portion 70 through the at least one terminal. In addition, the connecting portion 70 may be bent, which enables the electrical connection between the connector 80 and a main circuit board (not shown) of an electrical device to which the display apparatus 1 is coupled; thus, the display circuit board 40 may be electrically connected to the main circuit board.

Because the connector 80 is connected to the exposed first conductive layer CL1 of the connecting portion 70 through at least one terminal, the connection between the connecting portion 70 and the connector 80 may be unstable when the connecting portion 70 is bent. Accordingly, even when the connecting portion 70 is bent, the reinforcing portion 90 may be disposed on the lower portion of the connecting portion 70, on which the connector 80 is disposed, to secure the rigidity of a portion of the connecting portion 70 that overlaps the connector 80.

In the plan view, the reinforcing portion 90 may be disposed on the lower portion of the connecting portion 70 to overlap the connector 80. That is, the connector 80 may be disposed on the upper portion of the connecting portion 70 and the reinforcing portion 90 may be disposed on the lower portion of the connecting portion 70 with the connecting portion 70 therebetween. In an embodiment, the reinforcing portion 90 may include a layer with the same structure as that of the second group layer 62 of the body portion 60. In an embodiment, the reinforcing portion 90 may include the third conductive layer CL3, the second insulating film layer IF2, and the fourth conductive layer CL4 which are sequentially stacked, for example.

Each layer of the reinforcing portion 90 may not be continuous with each layer of the second group layer 62 of the body portion 60 and may be disconnected. That is, in the plan view, because the reinforcing portion 90 is disposed only in a region corresponding to the connector 80, the reinforcing portion 90 may be discontinued from the second group layer 62 of the body portion 60 and thus disposed in an island form. In this case, the reinforcing portion 90 may have a shape corresponding to the planar shape of the connector 80, and the shape of the reinforcing portion 90 may be, e.g., a rectangle, a circle, or the like.

In embodiments, the reinforcing portion 90 includes the layer with the same structure as that of the display circuit board 40, in particular, the second group layer 62 of the body portion 60, and thus, the reinforcing portion 90 may be simply manufactured while securing the rigidity of the connecting portion 70. In an embodiment, when stainless steel is used for the reinforcing portion 90, laser removal is performed on a layer of the second group layer 62 among the layers of the first group layer 61 and the second group layer 62 in a portion of the reinforcing portion 90, which corresponds to the connecting portion 70, to form the connecting portion 70, and then, the reinforcing portion 90 including stainless steel needs to be attached to the lower portion of the connecting portion 70 in a portion corresponding to the connector 80, for example. In embodiments, the layers of the second group layer 62 may not be removed from the lower portion of the connector 80 to form the reinforcing portion 90. That is, during the formation of the connecting portion 70, the layer of the second group layer 62 is not removed from the portion corresponding to the connector 80 and is removed only from the portion not corresponding to the connector 80 such that the connecting portion 70 and the reinforcing portion 90 may be simultaneously formed. Accordingly, the manufacturing processes may be simplified. Moreover, compared to when stainless steel is used for the reinforcing portion 90, it is possible to achieve a reduced thickness of the reinforcing portion 90 and cost savings in manufacturing by avoiding the use of expensive stainless steel.

In an embodiment, the lower portion of the reinforcing portion 90 may be electrically connected to ground. In detail, the fourth conductive layer CL4, which is the lower conductive layer of the reinforcing portion 90, may be connected to the ground and used as a ground layer. In addition, the fourth conductive layer CL4 of the reinforcing portion 90 may be grounded to a ground region of the electronic device to which the display apparatus 1 is coupled. Accordingly, the driving characteristics of the display apparatus 1 and the electronic device may be improved.

Also, in an embodiment, the reinforcing portion 90 may further include a prepreg layer PP. The reinforcing portion 90 may be attached to the lower portion of the connecting portion 70, e.g., the third coverlay layer CV3, by the prepreg layer PP. In an embodiment, the prepreg layer PP may be a layer in which resin is impregnated with reinforced fabric. The prepreg layer PP may be in a gel form and attach the reinforcing portion 90 to the connecting portion 70 and upon curing, the prepreg layer PP may provide relatively great rigidity to the reinforcing portion 90. Accordingly, the reinforcing portion 90 may have greater rigidity, compared to when the reinforcing portion 90 is attached to the connecting portion 70 by a general adhesive layer. Also, the prepreg layer PP of the reinforcing portion 90 may be disposed in the same process whereby the prepreg layer PP is disposed to adhere the first group layer 61 and the second group layer 62 of the body portion 60, thereby simplifying the process.

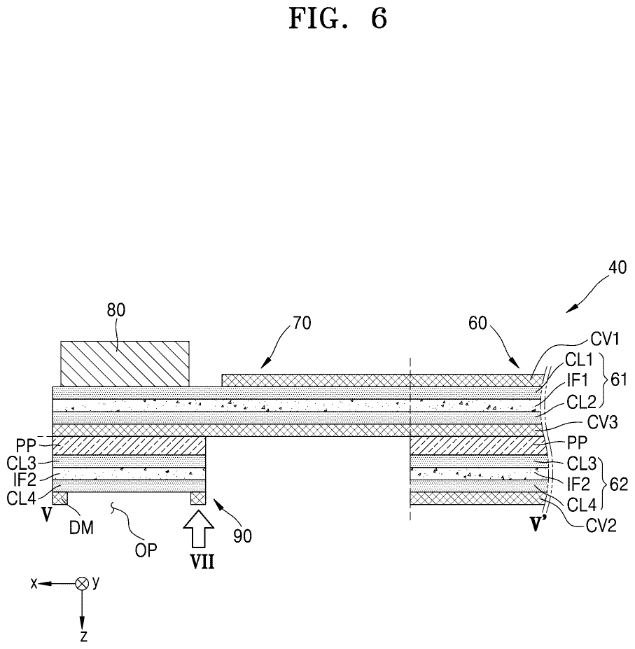

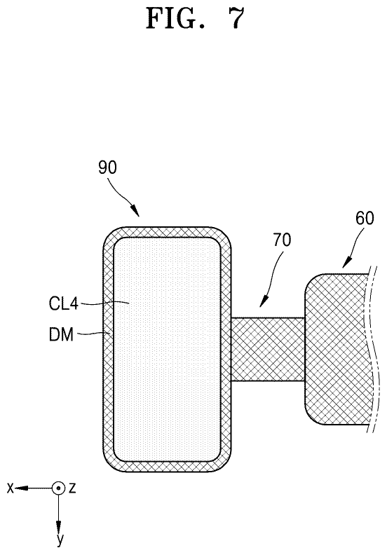

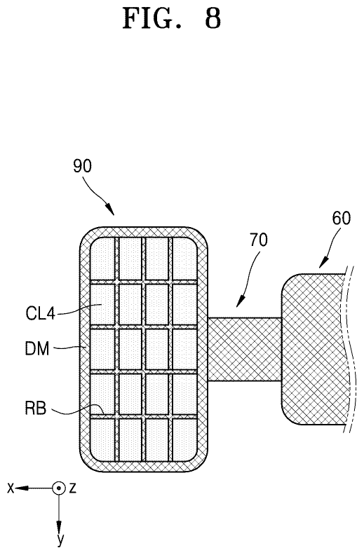

FIG. 6 is a schematic cross-sectional view of an embodiment of a display apparatus, which is similar to FIG. 5. FIG. 7 is a schematic bottom view showing an embodiment of a lower portion of a reinforcing portion and showing the display apparatus of FIG. 6 in a VII direction. FIG. 8 is a schematic bottom view showing an embodiment of the lower portion of the reinforcing portion, which is similar to FIG. 7.

Referring to FIGS. 6 and 7, the display circuit board 40 may further include a dam portion DM. The dam portion DM may be disposed on the lower portion of the reinforcing portion 90. The dam portion DM may be disposed over the fourth conductive layer CL4 that is the lower conductive layer of the reinforcing portion 90 and define an opening OP exposing at least a portion of the fourth conductive layer CL4. In this case, in an embodiment, the dam portion DM may be the layer including the same material as that of the second coverlay layer CV2 covering the second group layer 62 of the body portion 60.

The dam portion DM may expose the fourth conductive layer CL4 of the reinforcing portion 90 to make the fourth conductive layer CL4 contact the ground area of the electronic device and reinforce the rigidity of the reinforcing portion 90. In an embodiment, in the plan view, the dam portion DM may be disposed as a closed circuit along the periphery of the reinforcing portion 90. That is, the dam portion DM may be disposed in a loop shape along the periphery of the reinforcing portion 90 to define the opening OP. In this case, the dam portion DM may also prevent cracks from being generated in the conductive layers when punched to form the connecting portion 70 and the outer periphery of the reinforcing portion 90.

Referring to FIG. 8, the dam portion DM may further include a rib RB disposed to cross the opening OP. In this case, similar to the description provided above, the rib RB may be the same layer including the same material as that of the second coverlay layer CV2. The rib RB may be disposed in a grid pattern, as shown in FIG. 8. In an alternative embodiment, in another embodiment, a plurality of ribs RB may be provided in parallel and extend in a direction. As described, the rib RB may expose the fourth conductive layer CL4 of the reinforcing portion 90 while reinforcing the rigidity of the reinforcing portion 90.

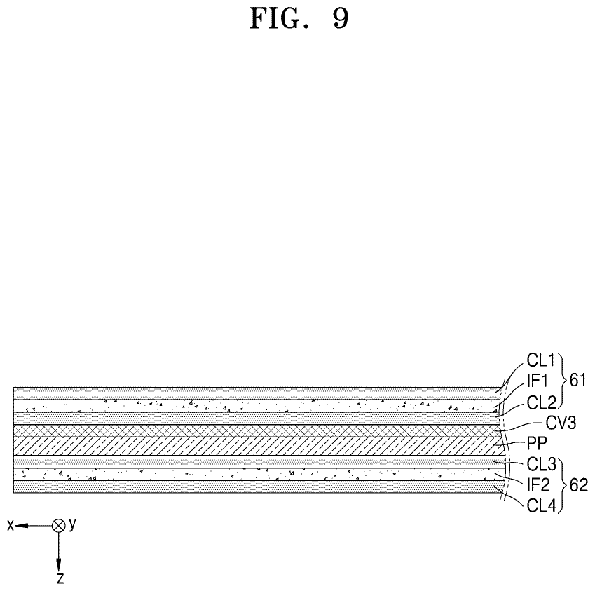

FIGS. 9 to 12 are schematic diagrams of an embodiment of a method of manufacturing a display apparatus.

Referring to FIG. 9, a structure layer of the first group layer 61 and a structure layer of the second group layer 62 may be stacked. In this case, the structure layer of the second group layer 62 may be attached to the structure layer of the first group layer 61 by the prepreg layer PP. In this case, the third coverlay layer CV3 may be disposed between the first group layer 61 and the second group layer 62. That is, the first conductive layer CL1, the first insulating film layer IF1, the second conductive layer CL2, the third coverlay layer CV3, the prepreg layer PP, the third conductive layer CL3, the second insulating film layer IF2, and the fourth conductive layer CL4 may be sequentially stacked from the top of the display circuit board 40 to the bottom thereof in a thickness direction of the display circuit board 40.

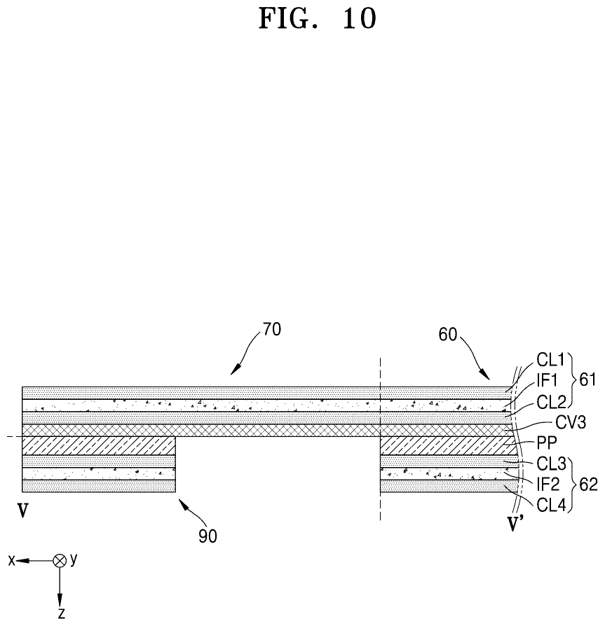

Referring to FIG. 10, a portion of the display circuit board 40 may be removed. In an embodiment, a portion of the display circuit board 40 may be laser-etched. In detail, the structure layer of the second group layer 62 may be etched in some portions of the display circuit board 40, thus forming the connecting portion 70, for example. In this case, in a portion in which the connector 80 is to be disposed (e.g., mounted), the structure layer of the second group layer 62 may not be etched. That is, in the plan view, a portion of the second group layer 62, which overlaps the connector 80 to be disposed (e.g., mounted), may remain unetched, while a portion of the second group layer 62, which does not overlap the connector 80 to be disposed (e.g., mounted), may be etched such that the connecting portion 70 and the reinforcing portion 90 may be simultaneously formed, where the second group layer 62 may be disposed on the lower portion of the connecting portion 70. In this case, the second group layer 62 may be laser-etched to surround the periphery of the reinforcing portion 90 while leaving the portion of the second group layer 62 that overlaps the connector 80 to be disposed (e.g., mounted), thus, the reinforcing portion 90 may be formed in an island shape.

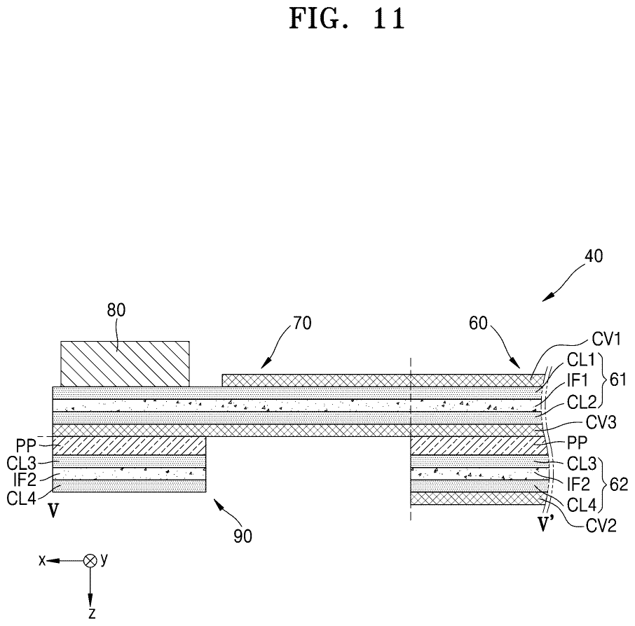

Referring to FIG. 11, the first coverlay layer CV1 and the second coverlay layer CV2 may be arranged to cover the upper conductive layer of the first group layer 61 and the lower conductive layer of the second group layer 62, respectively. In this case, the first coverlay layer CV1 may be disposed to cover the body portion 60 and the upper conductive layer of the connecting portion 70, e.g., the first conductive layer CL1. Also, the first coverlay layer CV1 may expose a portion of the first conductive layer CL1 of the connecting portion 70 to make the connector 80, which is to be disposed (e.g., mounted) on the connecting portion 70, contact the first conductive layer CL1. The second coverlay layer CV2 may be disposed to cover the lower conductive layer of the body portion 60, e.g., the fourth conductive layer CL4.

The illustrated embodiment is described based on a case where the second group layer 62 is etched and then the coverlay layer is disposed, but the disclosure is not limited thereto. In another embodiment, it may be understood that the coverlay layer may be first disposed and then the second group layer 62 may be etched.

Then, the display circuit board 40 may be punched to form the outer periphery of the display circuit board 40 of FIGS. 1 and 2. In addition, the connector 80 may be disposed (e.g., mounted) on the punched display circuit board 40.

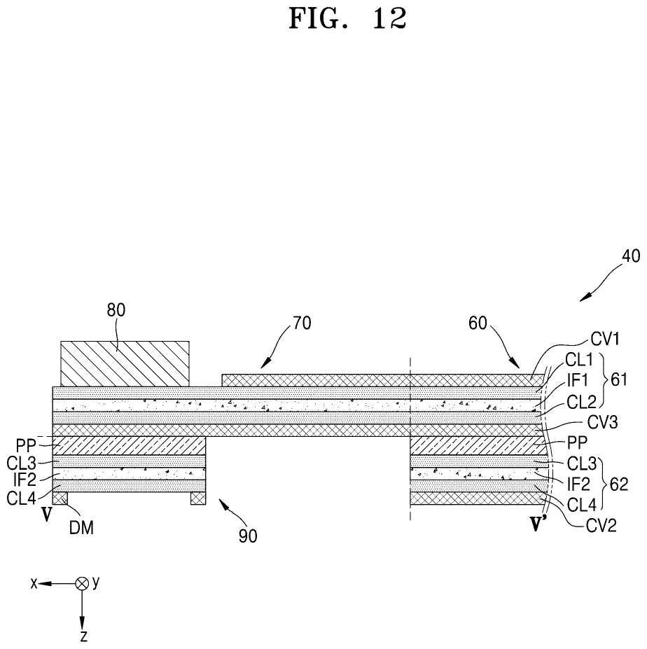

Referring to FIG. 12, as described above, when the second coverlay layer CV2 is disposed, a dam portion DM may also be disposed in the same process. In detail, the second coverlay layer CV2 and the dam portion DM may include the same material, e.g., polyimide. In an embodiment, the second coverlay layer CV2 and the dam portion DM may both be in a film form and attached to the fourth conductive layer CL4.

According to the embodiments, the quality of a display circuit board may be improved, and manufacturing processes thereof may be simplified.

The effects of the disclosure are not limited to those stated herein, and other effects that are not mentioned may be clearly understood by one of ordinary skill in the art from the description of claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a display panel comprising a plurality of pixels; and
a display circuit board which transmits a signal to the display panel, the display circuit board comprising:
a first group layer and a second group layer which are sequentially stacked in a thickness direction of the display circuit board;
a body portion comprising the first group layer and the second group layer;
a connecting portion extending from a side of the body portion and comprising a layer having a same structure as a structure of the first group layer;
a connector disposed on an upper portion of the connecting portion; and
a reinforcing portion disposed on a lower portion of the connecting portion to overlap the connector in a plan view and comprising a layer having a same structure as a structure of the second group layer.

2. The display apparatus of claim 1, wherein the first group layer of the body portion is connected to the connecting portion, and the second group layer of the body portion is discontinued from the connecting portion and the reinforcing portion.

3. The display apparatus of claim 1, wherein the reinforcing portion is discontinued from the second group layer of the body portion and disposed in an island shape.

4. The display apparatus of claim 1, wherein the reinforcing portion comprises at least one conductive layer, and the at least one conductive layer is exposed and connected to ground.

5. The display apparatus of claim 4, wherein the reinforcing portion comprises:
a first conductive layer disposed on a lower portion of the connecting portion, a second conductive layer disposed on a lower portion of the first conductive layer, and an insulating film layer disposed between the first conductive layer and the second conductive layer.

6. The display apparatus of claim 5, wherein the reinforcing portion further comprises a prepreg layer disposed on the first conductive layer.

7. The display apparatus of claim 1, wherein the display circuit board further comprises a dam portion disposed under the reinforcing portion and defining an opening exposing at least a portion of the reinforcing portion.

8. The display apparatus of claim 7, wherein the body portion further comprises a coverlay layer disposed on a lower portion of the second group layer, and the dam portion comprises a same material as a material of the coverlay layer.

9. The display apparatus of claim 7, wherein the dam portion is disposed in a loop shape along a periphery of the reinforcing portion.

10. The display apparatus of claim 7, wherein the dam portion further comprises a rib which crosses the opening.

11. The display apparatus of claim 10, wherein the rib is disposed in a grid pattern.

12. A method of manufacturing a display apparatus, the method comprising:
forming a display circuit board; and
connecting the display circuit board to a display panel,
wherein the forming the display circuit board comprises:
forming a stack structure comprising a body portion by sequentially stacking a first group layer and a second group layer in a thickness direction of the display circuit board;
forming a connecting portion connected to the body portion by removing the second group layer from a side of the body portion; and
when the second group layer is removed, forming a reinforcing portion by leaving a portion of the second group layer which overlaps a connector to be disposed on the connecting portion, the second group layer being disposed on a lower portion of the connecting portion.

13. The method of claim 12, further comprising arranging the connector on an upper portion of the connecting portion.

14. The method of claim 12, wherein the second group layer is discontinued between the body portion and the reinforcing portion.

15. The method of claim 14, wherein the reinforcing portion is discontinued from the second group layer of the body portion and disposed in an island shape.

16. The method of claim 12, wherein the reinforcing portion comprises at least one conductive layer, and the at least one conductive layer is exposed and connected to ground.

17. The method of claim 16, wherein the reinforcing portion comprises:
a first conductive layer disposed on the lower portion of the connecting portion, a second conductive layer disposed on a lower portion of the first conductive layer, and an insulating film layer disposed between the first conductive layer and the second conductive layer.

18. The method of claim 12, further comprising forming a dam portion comprising an opening defined in a lower portion of the reinforcing portion and exposing at least a portion of the reinforcing portion.

19. The method of claim 18, wherein the dam portion and a coverlay layer are formed through a same process, and the coverlay layer is disposed on a lower portion of the body portion.

20. The method of claim 18, wherein the dam portion is disposed in a loop shape along a periphery of the reinforcing portion.
